(19) United States
(12) Patent Application Publication
(10) Pub. No.: US 2025/0126988 A1
(43) Pub. Date: Apr. 17, 2025

(54) DISPLAY SUBSTRATE AND PREPARATION METHOD THEREFOR, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Ke LIU, Beijing (CN); Ling SHI, Beijing (CN); Hui LU, Beijing (CN); Zhu WANG, Beijing (CN)

(21) Appl. No.: 18/293,783

(22) PCT Filed: Aug. 4, 2022
(86) PCT No.: PCT/CN2022/110291

§ 371 Date: Jan. 31, 2024

(30) Foreign Application Priority Data
Aug. 11, 2021 (CN) 202110917746.9

(51) Int. Cl. H10K 59/131; H10K 59/126; H10K 102/00

(52) U.S. Cl. CPC H10K 59/131; H10K 59/126; H10K 2102/311

(57) ABSTRACT

A display substrate and a manufacturing method therefor, and a display apparatus are provided. The display substrate includes a plurality of circuit units, a scan signal line for providing a scan signal for the circuit units, and a first power supply line (51) for providing a power supply signal; wherein at least one circuit unit includes a pixel drive circuit, the pixel drive circuit includes a first shield electrode (34), which is connected to the first power supply line (51), an orthographic projection of the first shield electrode (34) on a plane of the display substrate at least partially overlaps an orthographic projection of the scan signal line on the plane of display substrate.

### CROSS-REFERENCE TO RELATED APPLICATIONS

The present application is a U.S. National Phase Entry of International Application PCT/CN2022/110291 having an international filing date of Aug. 4, 2022, which claims priority to Chinese Patent Application No. 202110917746.9 filed to the CNIPA on Aug. 11, 2021 and entitled ““Display Substrate and Preparation Method Therefor, and Display Apparatus”, and the entire contents disclosed in the above-mentioned applications are incorporated into the present application by reference.

### TECHNICAL FIELD

The present disclosure relates to, but is not limited to, the field of display technologies, and particularly to a display substrate and a manufacturing method therefor, and a display device.

### BACKGROUND

An Organic Light Emitting Diode (OLED) and a Quantum-dot Light Emitting Diode (QLED) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In one aspect, the present disclosure provides a display substrate including a plurality of circuit units, a scan signal line supplying a scan signal to the circuit units, and a first power supply line supplying a power supply signal; at least one circuit unit includes a pixel drive circuit including a first shield electrode connected with the first power supply line, an orthographic projection of the first shield electrode on a plane of the display substrate is at least partially overlapped with an orthographic projection of the scan signal line on the plane of the display substrate.

In an exemplary implementation, the pixel drive circuit further includes a drive transistor and a first plate and a second plate forming a storage capacitor, an orthographic projection of the first plate on the plane of the display substrate is at least partially overlapped with an orthographic projection of the second plate on the plane of the display substrate; the first shield electrode is connected with the second plate, and the second plate is connected with the first power supply line through a via.

In an exemplary implementation, the pixel drive circuit further includes a compensation transistor and a first connection electrode, a first end of the first connection electrode is connected with a first region of an active layer in the compensation transistor through a via, a second end of the first connection electrode is connected with the first plate through a via, and an orthographic projection of the first connection electrode on the plane of the display substrate is at least partially overlapped with an orthographic projection of the scan signal line on the plane of the display substrate.

In an exemplary implementation, the orthographic projection of the first shield electrode on the plane of the display substrate and the orthographic projection of the scan signal line on the plane of the display substrate have a first overlapped area, and the orthographic projection of the first connection electrode on the plane of the display substrate and the orthographic projection of the scan signal line on the plane of the display substrate have a second overlapped area, the second overlapped area is at least partially overlapped with the first overlapped area.

In an exemplary implementation, the second overlapped area is within the range of the first overlapped area.

In an exemplary implementation, the first overlapped area has a first width and the second overlapped area has a second width; the first width is larger than the second width, and the first width and the second width are dimensions in the first direction.

In an exemplary implementation, the second width is 40% to 60% of the first width L1. In an exemplary implementation, the first width is 2.5 μm to 3.0 μm.

In an exemplary implementation, the second width is 1.3 μm to 2.0 μm.

In an exemplary implementation, a main body portion of the scan signal line extends in a first direction, and a main body portion of the first shield electrode extends in a second direction, wherein the first direction intersects the second direction; the first shield electrode is disposed at a side of the second plate close to the scan signal line, and an orthographic projection of an end of the first shield electrode away from the second plate on the plane of the display substrate is at least partially overlapped with an orthographic projection of the scan signal line on the plane of the display substrate.

In an exemplary implementation, the first shield electrode and the second plate are disposed in the same layer and form an integrated structure connected with each other.

In an exemplary embodiment, in a plane perpendicular to the display substrate, the display substrate includes a semiconductor layer, a first conductive layer, a second conductive layer, a third conductive layer, and a fourth conductive layer that are sequentially disposed on a base substrate, and an insulation layer is disposed between the first conductive layer and the second conductive layer, between the second conductive layer and the third conductive layer, and between the third conductive layer and the fourth conductive layer; the first shield electrode, the first connection electrode and the scan signal line are located in different conductive layers.

In an exemplary implementation, the scan signal line is disposed in the first conductive layer, the first shield electrode is disposed in the second conductive layer, and the first connection electrode is disposed in the third conductive layer.

In an exemplary implementation, the semiconductor layer includes active layers of a plurality of transistors in the pixel drive circuit, the first conductive layer includes a scan signal line, gate electrodes of the plurality of transistors, and a first plate of the storage capacitor, the second conductive layer includes the first shield electrode and a second plate of the storage capacitor, the third conductive layer includes a data signal line and a first connection electrode, and the fourth conductive layer includes a first power supply line.

In an exemplary implementation, the second conductive layer further includes a second shield electrode, the second shield electrode includes a first sub-electrode and a second sub-electrode connected with each other, an orthographic projection of the first sub-electrode on the base substrate is at least partially overlapped with an orthographic projection of the data signal line on the base substrate, an orthographic projection of the second sub-electrode on the base substrate is located between the orthographic projection of the data signal line on the base substrate and an orthographic projection of the first connection electrode on the base substrate.

In an exemplary implementation, the second shield electrode is connected with the first power supply line through a via.

In another aspect, the present disclosure further provides a display apparatus, including the display substrate described above.

In another aspect, the present disclosure further provides a method for manufacturing a display substrate, including:
forming a plurality of circuit units, a scan signal line supplying a scan signal to the circuit units and a first power supply line supplying a power supply signal on the base substrate, wherein at least one circuit unit includes a pixel drive circuit including a first shield electrode connected with the first power supply line, and an orthographic projection of the first shield electrode on the base substrate is at least partially overlapped with an orthographic projection of the scan signal line on the base substrate.

After the drawings and the detailed descriptions are read and understood, the other aspects may be comprehended.

### BRIEF DESCRIPTION OF DRAWINGS

The accompany drawings are used to provide further understanding of the technical solution of the present disclosure, and form a part of the description. The accompany drawings and embodiments of the present disclosure are adopted to explain the technical solution of the present disclosure, and do not form limits to the technical solution of the present disclosure.

FIG. 1 is a schematic diagram of a structure of a display apparatus.

FIG. 2 is a schematic diagram of a planar structure of a display substrate;

FIG. 3 is a schematic diagram of a sectional structure of a display substrate;

FIG. 4 is a schematic diagram of an equivalent circuit of a pixel drive circuit.

FIG. 5 is a working timing diagram of a pixel drive circuit.

FIG. 6 is a schematic diagram of a structure of a display substrate according to an exemplary embodiment of the present disclosure;

FIG. 7 is a schematic diagram after a pattern of a semiconductor layer is formed according to an exemplary embodiment of the present disclosure.

FIG. 8a is a schematic diagram after a pattern of a first conductive layer is formed according to an exemplary embodiment of the present disclosure.

FIG. 8b is a schematic planar view of the first conductive layer in FIG. 8a.

FIG. 9a is a schematic diagram after a pattern of a second conductive layer is formed according to an exemplary embodiment of the present disclosure;

FIG. 9b is a schematic plan view of the second conductive layer in FIG. 9a.

FIG. 10a is a schematic diagram after a pattern of a fourth insulation layer is formed according to an exemplary embodiment of the present disclosure.

FIG. 10b is a schematic plan view of multiple vias in FIG. 10a.

FIG. 11a is a schematic diagram after a pattern of a third conductive layer is formed according to an exemplary embodiment of the present disclosure;

FIG. 11b is a schematic plan view of the third conductive layer in FIG. 11.

FIG. 12a is a schematic diagram after a pattern of a first planarization layer is formed according to an exemplary embodiment of the present disclosure.

FIG. 12b is a schematic plan view of multiple vias in FIG. 12a.

FIG. 13a is a schematic diagram of a display substrate after a pattern of a fourth conductive layer is formed according to the present disclosure.

FIG. 13b is a schematic plan view of the fourth conductive layer in FIG. 13a.

FIG. 14 is a schematic diagram after a pattern of a second planarization layer is formed according to an exemplary embodiment of the present disclosure;

FIG. 15 is a schematic diagram after a pattern of an anode is formed according to an exemplary embodiment of the present disclosure.

FIG. 16 is a schematic diagram of a display substrate after a pattern of a pixel define layer is formed according to an exemplary embodiment of the present disclosure.

### REFERENCE SIGNS ARE DESCRIBED AS FOLLOWS

Reference signs are described as follows.

| | | |
|---|---|---|
| 11-first active layer; | 12-second active layer; | 13-third active layer; |
| 14-fourth active layer; | 15-fifth active layer; | 16-sixth active layer; |
| 17-seventh active | 21-first scan signal | 21-1 - gate block; |
| layer; | line; | |
| 22-second scan | 23-light emitting | 24-first plate; |
| signal line | control line; | |
| 31-Initial signal line; | 32-second plate; | 33-plate connection |
| | | line; |
| 34-first shield electrode; | 35-second shield | 35-1-first sub- |
| | electrode; | electrode; |
| 35-2-second sub- | 36-opening; | 41-first connection |
| electrode; | | electrode; |
| 42-second | 43-third connection | 44-data signal line; |
| connectionelectrode; | electrode; | |
| 51-first power supply | 52-anode connection | 61-anode; |
| line; | electrode; | |
| 71-pixel opening; | 101-base substrate; | 102-drive circuit layer; |
| 103-light emitting | 104 - encapsulation | 210-transistor; |
| structure layer; | layer; | |
| 211-storage capacitor; | 301-anode; | 302-pixel definition |
| | | layer; |
| 303-organic emitting | 304-cathode; | 401-first encapsulation |
| layer; | | layer; |
| 402-second | 403-third | |
| encapsulation layer; | encapsulation layer. | |

### DETAILED DESCRIPTION

To make the objectives, technical solutions, and advantages of the present disclosure clearer, the embodiments of the present disclosure will be described in detail below in combination with the accompany drawings. It is to be noted that the implementations may be implemented in various forms. Those of ordinary skill in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other in case of no conflicts.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in number but only to avoid the confusion of composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limits to the present disclosure. The positional relationships between the composition elements may be changed as appropriate according to the direction where each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, the term may be fixed connection, or detachable connection, or integral connection. The term may be mechanical connection or electric connection. The term may be direct connection, or indirect connection through an intermediate, or communication inside two elements. Those of ordinary skill in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. It is to be noted that in the specification, the channel region refers to a main region that a current flows through.

In the specification, a first electrode may be the drain electrode, and a second electrode may be the source electrode. Alternatively, the first electrode may be a source electrode, and the second electrode may be a drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode”, as well as the “source terminal” and the “drain terminal”, are interchangeable in the specification.

In the specification, “electric connection” includes connection of the composition elements through an element with a certain electric action. “An element with a certain electric action” is not particularly limited as long as electric signals between the connected composition elements may be sent and received. Examples of “an element with a certain electric action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within process and measurement error ranges are allowed.

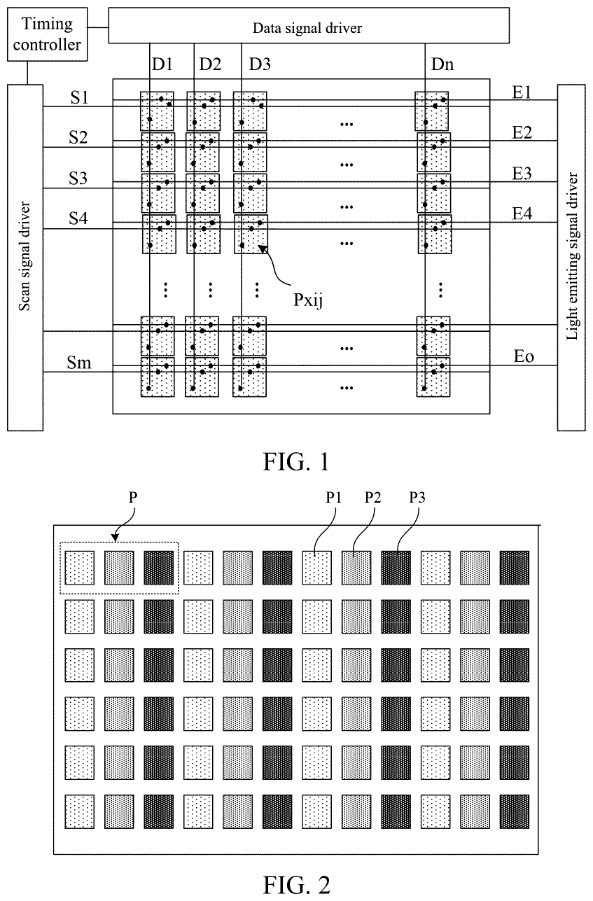

FIG. 1 is a schematic diagram of a structure of a display apparatus. As shown in FIG. 1, the display apparatus may include a timing controller, a data driver, a scan driver, a light emitting driver, a plurality of scan signal lines, a plurality of data signal lines, a plurality of light emitting signal lines and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include multiple sub-pixels Pxij, wherein i and j may be natural numbers. At least one sub-pixel Pxij may include a circuit unit and a light emitting device connected with the circuit unit, wherein the circuit unit may include at least one pixel drive circuit. In an exemplary implementation, the timing controller may provide a grayscale value and a control signal suitable for the specification of the data signal driver to the data signal driver, may provide a clock signal, a scan start signal, etc. suitable for the specification of the scan driver to the scan driver, and may provide a clock signal, an emission stop signal, etc. suitable for the specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a row of pixels as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting a scan start signal provided in a form of an on-level pulse to a next-stage circuit under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a planar structure of a display substrate. In an exemplary implementation, the display substrate may include multiple pixel units P arranged in a matrix manner, at least one pixel unit P may include one first sub-pixel P1 emitting a first color light, one second sub-pixel P2 emitting a second color light, and one third sub-pixel P3. Each of the three sub-pixels may include a circuit unit and a light emitting device. The circuit unit may include a scan signal line, a data signal line and a light emitting signal line and a pixel drive circuit. The pixel drive circuit is respectively connected with the scan signal line, the data signal line, and the light emitting signal line. The pixel drive circuit is configured to receive the data voltage transmitted by the data signal line and output a corresponding current to the light emitting device under the control of the scan signal line and the light emitting signal line. The light emitting device in each sub-pixel is connected with a pixel drive circuit of a sub-pixel where the light emitting device is located, and is configured to emit light with corresponding brightness in response to a current output by the pixel drive circuit of the sub-pixel where the light emitting device is located.

In an exemplary implementation mode, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be provided side by side horizontally, side by side vertically, or in a manner like a Chinese character “ [symbol] ”. In an exemplary implementation, at least one pixel unit P may include four sub-pixels, and the present disclosure is not limited thereto.

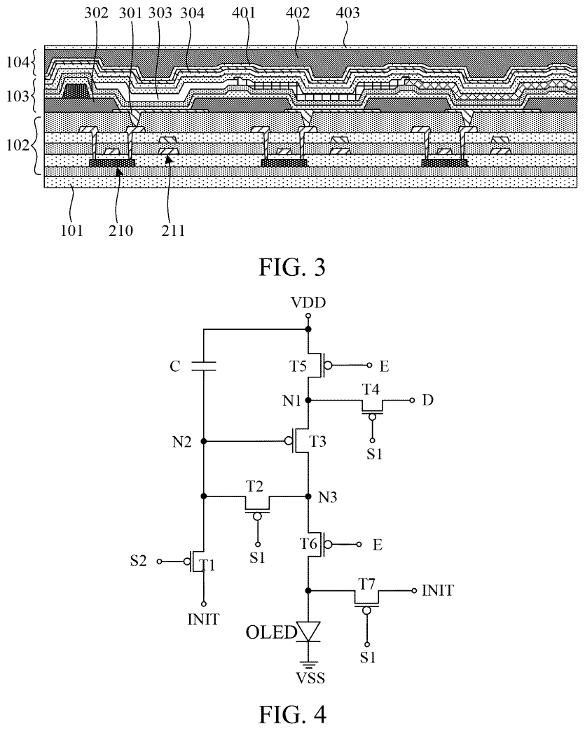

FIG. 3 is a schematic diagram of a sectional structure of a display substrate, and illustrates a structure of three sub-pixels of the display substrate. As shown in FIG. 3, on a plane perpendicular to the display substrate, the display substrate may include a drive circuit layer 102 disposed on a base substrate 101, a light emitting structure layer 103 disposed at a side of the drive circuit layer 102 away from the base substrate, and an encapsulation layer 104 disposed at a side of the light emitting structure layer 103 away from the base substrate. In some possible implementations, the display substrate may include another film layer, such as a post spacer, which is not limited in the present disclosure.

In an exemplary implementation mode, the base substrate 101 may be a flexible base substrate, or may be a rigid base substrate. The drive circuit layer 102 may include a plurality of signal lines and a plurality of circuit units, and at least one circuit unit may include a pixel drive circuit, the pixel drive circuit may include a plurality of transistors and a storage capacitor. In FIG. 3, only one drive transistor 210 and one storage capacitor 211 are taken as an example for illustration. The light emitting structure layer 103 may include a plurality of light emitting devices, at least one of which may include an anode 301, an organic emitting layer 303 and a cathode 304. The anode 301 is connected with the drain electrode of the drive transistor 210 through a via, the organic emitting layer 303 is connected with the anode 301, the cathode 304 is connected with the organic emitting layer 303, the organic emitting layer 303 emits light of a corresponding color under driving of the anode 301 and the cathode 304. The encapsulation layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 so as to prevent external water vapor from entering the light-emitting structure layer 103.

In an exemplary implementation, the organic emitting layer 303 may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) which are stacked. In an exemplary implementation mode, hole injection layers and electron injection layers of all sub-pixels may be connected together as a common layer, hole transport layers and electron transport layers of all the sub-pixels may be connected together as a common layer, hole block layers of all the sub-pixels may be connected together as a common layer, and emitting layers and electron block layers of adjacent sub-pixels may be slightly overlapped with each other, or may be isolated from each other.

In an exemplary implementation mode, the pixel drive circuit may have a structure of 3TIC, 4TIC, 5TIC, 5T2C, 6TIC, 7TIC, or 8TIC. FIG. 4 is a schematic diagram of an equivalent circuit of a pixel drive circuit. As shown in FIG. 4, the pixel drive circuit may include seven transistors (a first transistor T1 to a seventh transistor T7), one storage capacitor C. The pixel drive circuit is connected with seven signal lines (a data signal line D, a first scan signal line S1, a second scan signal line S2, a light emitting signal line E, an initial signal line INIT, a first power supply line VDD, and a second power supply line VSS) respectively.

In an exemplary implementation, the pixel drive circuit may include a first node N1, a second node N2, and a third node N3. The first node N1 is connected with a first electrode of the third transistor T3, a second electrode of the fourth transistor T4 and a second electrode of the fifth transistor T5 respectively. The second node N2 is connected with a second electrode of the first transistor, a first electrode of the second transistor T2, a control electrode of the third transistor T3 and a second end of the storage capacitor C respectively. The third node N3 is connected with a second electrode of the second transistor T2, a second electrode of the third transistor T3 and a first electrode of the sixth transistor T6 respectively.

In an exemplary implementation, a first end of the storage capacitor C is connected with the first power supply line VDD, and the second end of the storage capacitor C is connected with the second node N2, i.e., the second end of the storage capacitor C is connected with the control electrode of the third transistor T3.

The control electrode of the first transistor T1 is connected with the second scan signal line S2, the first electrode of the first transistor T1 is connected with the initial signal line INIT, and the second electrode of the first transistor is connected with the second node N2. When a scan signal with an on-level is applied to the second scan signal line S2, the first transistor T1 transmits an initialization voltage to the control electrode of the third transistor T3 so as to initialize a charge amount of the control electrode of the third transistor T3.

The control electrode of the second transistor T2 is connected with the first scan signal line S1, the first electrode of the second transistor T2 is connected with the second node N2, and the second electrode of the second transistor T2 is connected with the third node N3. When a scan signal with an on-level is applied to the first scan signal line S1, the second transistor T2 enables the control electrode of the third transistor T3 to be connected with the second electrode of the third transistor T3.

The control electrode of the third transistor T3 is connected with the second node N2, i.e., the control electrode of the third transistor T3 is connected with the second end of the storage capacitor C, the first electrode of the third transistor T3 is connected with the first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

The control electrode of the fourth transistor T4 is connected with the first scan signal line S1, the first electrode of the fourth transistor T4 is connected with the data signal line D, and the second electrode of the fourth transistor T4 is connected with the first node N1. When a scan signal with an on-level is applied to the first scan signal line S1, the fourth transistor T4 enables a data voltage of the data signal line D to be input to the pixel drive circuit.

The control electrode of the fifth transistor T5 is connected with the light emitting signal line E, the first electrode of the fifth transistor T5 is connected with the first power supply line VDD, and the second electrode of the fifth transistor T5 is connected with the first node N1. The control electrode of the sixth transistor T6 is connected with the light emitting signal line E, the first electrode of the sixth transistor T6 is connected with the third node N3, and the second electrode of the sixth transistor T6 is connected with the first electrode of the light emitting device. When a light emitting signal with an on-level is applied to the light emitting signal line E, the fifth transistor T5 and the sixth transistor T6 enable the light emitting device to emit light by forming a drive current path between the first power supply line VDD and the second power supply line VSS.

The control electrode of the seventh transistor T7 is connected with the first scan signal line S1, the first electrode of the seventh transistor T7 is connected with the initial signal line INIT, and the second electrode of the seventh transistor T7 is connected with the first electrode of the light emitting device. When a scan signal with an on-level is applied to the first scan signal line S1, the seventh transistor T7 transmits an initialization voltage to the first electrode of the light emitting device so as to initialize a charge amount accumulated in the first electrode of the light emitting device or release a charge amount accumulated in the first electrode of the light emitting device.

In an exemplary implementation mode, the light emitting device may be an OLED including a first electrode (anode), an organic emitting layer, and a second electrode (cathode) which are stacked, or may be a QLED including a first electrode (anode), a quantum dot emitting layer, and a second electrode (cathode) which are stacked.

In an exemplary implementation, the second electrode of the light emitting device is connected with the second power supply line VSS, a signal of the second power supply line VSS is a low-level signal, and a signal of the first power supply line VDD is a high-level signal continuously provided. The first scan signal line S1 is a scan signal line in a pixel drive circuit in a current display row, and the second scan signal line S2 is a scan signal line in a pixel drive circuit in a previous display row, that is, for the n-th display row, the first scan signal line S1 is S(n), and the second scan signal line S2 is S(n−1). The second scan signal line S2 in the pixel drive circuit in the current display row and the first scan signal line S1 in the pixel drive circuit in the previous display row are the same signal line, such that signal lines of a display panel can be reduced, so as to achieve a narrow bezel of the display panel.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation mode, for the first transistor T1 to the seventh transistor T7, low temperature poly silicon thin film transistors may be adopted, or oxide thin film transistors may be adopted, or both a low temperature poly silicon thin film transistor and an oxide thin film transistor may be adopted. An active layer of a low temperature poly silicon thin film transistor may be made of Low Temperature Poly Silicon (LTPS for short), and an active layer of an oxide thin film transistor may be made of an oxide semiconductor (Oxide). The low temperature poly-silicon thin film transistors have advantages such as high migration rate and fast charging, and the oxide thin film transistors have advantages such as low leakage current. The low temperature poly-silicon thin film transistors and the oxide thin film transistors are integrated on one display substrate to form a low temperature polycrystalline oxide (LTPO) display substrate, so that the advantages of both the low temperature poly-silicon thin film transistors and the oxide thin film transistors can be utilized, low-frequency drive transistor can be realized, power consumption can be decreased, and display quality can be improved.

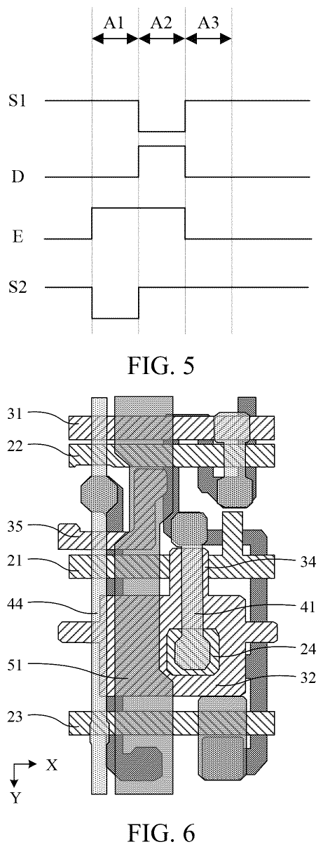

FIG. 5 is a working timing diagram of a pixel drive circuit. An exemplary embodiment of the present disclosure will be described below through a working process of the pixel drive circuit exemplified in FIG. 4. The pixel drive circuit in FIG. 4 includes seven transistors (a first transistor T1 to a seventh transistor T7) and one storage capacitor C, and the seven transistors are all P-type transistors.

In an exemplary implementation, the working process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is a low-level signal, so that the first transistor T1 is turned on, and a signal of the initial signal line INIT is provided to a second node N2 to initialize the storage capacitor C to clear an original data voltage in the storage capacitor. The signals of the first scan signal line S1 and the light emitting signal line E are high-level signals, so that the second transistor T2, the fourth transistor T4, the fifth transistor T5, the sixth transistor T6, and the seventh transistor T7 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd-|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization to ensure that the OLED does not emit light. A signal of the second scan signal line S2 is a high-level signal, so that the first transistor T1 is turned off. The signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is a low-level signal, so that the fifth transistor T5 and the sixth transistor T6 are turned on, and a power voltage output by the first power supply line VDD provides a drive voltage to the first electrode of the OLED through the turned-on fifth transistor T5, third transistor T3, and sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. Since the voltage of the second node N2 is Vd-|Vth|, the drive current of the third transistor T3 is as follows:

$$I = K * {( Vgs - Vth )}^{2} = K * {[ ( V d d - Vd + \vert Vth \vert ) - Vth ]}^{2} = K * {[ ( V d d - Vd ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

FIG. 6 is a schematic diagram of a structure of a display substrate according to an exemplary embodiment of the present disclosure, illustrating a planar structure of one pixel unit. As shown in FIG. 6, in a plane parallel to the display substrate, the display substrate may include a plurality of circuit units and a plurality of signal lines, the plurality of circuit units may be sequentially arranged along a first direction X to form a circuit unit row, the plurality of circuit units may be sequentially arranged along a second direction Y to form a circuit unit column, the plurality of circuit unit rows and the plurality of circuit unit columns constitute an array of circuit units arranged in an array, the first direction X intersects the second direction Y.

In an exemplary implementation, the plurality of signal lines may at least include a first scan signal line 21, a second scan signal line 22, a light emitting control line 23, an initial signal line 31, a data signal line 44, and a first power supply line 51, and at least one circuit unit may include a pixel drive circuit. The main body portions of the first scan signal line 21, the second scan signal line 22, the light emitting control line 23, and the initial signal line 31 may extend along the first direction X, and the main body portions of the data signal line 44 and the first power supply line 51 may extend along the second direction Y. In the present disclosure, A extends along a B direction means that A may include a main portion and a secondary portion connected with the main portion, the main portion is a line, a line segment, or a strip-shaped body, the main portion extends along the B direction, and a length of the main portion extends along the B direction is greater than a length of the secondary portion extends along another direction.

In an exemplary implementation, the first scan signal line 21 and the second scan signal line 22 are configured to supply a scan signal to the pixel drive circuit, the light emitting control line 23 is configured to supply a light emitting control signal to the pixel drive circuit, the initial signal line 31 is configured to supply an initial signal to the pixel drive circuit, the data signal line 44 is configured to supply a data signal to the pixel drive circuit, and the first power supply line 51 is configured to supply a power supply signal to the pixel drive circuit.

In an exemplary implementation, the pixel drive circuit may include a plurality of transistors and a storage capacitor, the plurality of transistors may include a first transistor T1 to a seventh transistor T7, the third transistor T3 is a drive transistor, and the storage capacitor may include a first plate 24 and a second plate 32, an orthographic projection of the first plate 24 on the plane of the display substrate at least partially overlapped with an orthographic projection of the second plate 32 on the plane of the display substrate.

In an exemplary implementation, a gate electrode of the first transistor T1 is connected with the second scan signal line 22, a first electrode of the first transistor T1 is connected with the initial signal line 31, and a second electrode of the first transistor T1 is connected with a first electrode of the second transistor T2, a gate electrode of the third transistor T3, and the first plate 24 of the storage capacitor, respectively. A gate electrode of the second transistor T2 is connected with the first scan signal line 21, the first electrode of the second transistor T2 is connected with the second electrode of the first transistor T1, the gate electrode of the third transistor T3 and the first plate 24 of the storage capacitor, respectively, and a second electrode of the second transistor T2 is connected with a second electrode of the third transistor T3 and a first electrode of the sixth transistor T6, respectively. The gate electrode of the third transistor T3 is connected with the second electrode of the first transistor T1, the first electrode of the second transistor T2 and the first plate 24 of the storage capacitor, respectively, a first electrode of the third transistor T3 is connected with a second electrode of the fourth transistor T4 and a second electrode of the fifth transistor T5, respectively, and a second electrode of the third transistor T3 is connected with the second electrode of the second transistor T2 and the first electrode of the sixth transistor T6, respectively. A gate electrode of the fourth transistor T4 is connected to the first scan signal line 21, a first electrode of the fourth transistor T4 is connected to the data signal line 44, and the second electrode of the fourth transistor T4 is connected to the first electrode of the third transistor T3 and the second electrode of the fifth transistor T5, respectively. A gate electrode of the fifth transistor T5 is connected with the light emitting signal line 23, a first electrode of the fifth transistor T5 is connected with the first power supply line 51 and the second plate 32 for of the storage capacitor, respectively, and the second electrode of the fifth transistor T5 is connected with the first electrode of the third transistor T3 and the second electrode of the fourth transistor T4, respectively. A gate electrode of the sixth transistor T6 is connected with the light emitting signal line 23, the first electrode of the sixth transistor T6 is connected with the second electrode of the second transistor T2 and the second electrode of the third transistor T3, respectively, and a second electrode of the sixth transistor T6 is connected with a second electrode of the seventh transistor T7 and a first electrode of the light emitting device, respectively. A gate electrode of the seventh transistor T7 is connected with the second scan signal line 22, a first electrode of the seventh transistor T7 is connected with the initial signal line 31, and the second electrode of the seventh transistor T7 is connected with the second electrode of the sixth transistor T6 and the first electrode of the light emitting device.

In an exemplary implementation, the first plate 24 of the storage capacitor is connected with the second electrode of the first transistor T1, the first electrode of the second transistor T2 and the gate electrode of the third transistor T3, respectively, and the second plate 32 of the storage capacitor is connected with the first power supply line 51 and the first electrode of the fifth transistor T5, respectively.

In an exemplary implementation mode, the first plate 24 of the storage capacitor may serve as a gate electrode of the third transistor T3.

In an exemplary implementation, the pixel drive circuit may include a first shield electrode 34 configured to shield the influence of the voltage jump of the scan signal on the third transistor T3, which avoids the voltage jump of the scan signal affecting the performance of the drive transistor, and improves the display effect.

In an exemplary implementation, the first shield electrode 34 may be connected with the first power supply line 51, an orthographic projection of the first shield electrode 34 on the plane of the display substrate is at least partially overlapped with an orthographic projection of the first scan signal line 21 on the plane of the display substrate.

In an exemplary implementation, the pixel drive circuit may include a first connection electrode 41 configured as the second electrode of the first transistor T1 and the first electrode of the second transistor T2. The main body portion of the first connection electrode 41 may extend along the second direction Y. A first end of the first connection electrode 41 is connected with a first region of the active layer in the second transistor T2 through a via, and a second end of the first connection electrode 41 is connected with the first plate 24 (i.e., the gate electrode of the third transistor T3) through a via. An orthographic projection of the first connection electrode 41 on the plane of the display substrate is at least partially overlapped with an orthographic projection of the first scan signal line 21 on the plane of the display substrate.

In an exemplary implementation, the orthographic projection of the first shield electrode 34 on the plane of the display substrate and the orthographic projection of the first scan signal line 21 on the plane of the display substrate have a first overlapped area, and the orthographic projection of the first connection electrode 41 on the plane of the display substrate and the orthographic projection of the first scan signal line 21 on the plane of the display substrate have a second overlapped area, the second overlapped area is at least partially overlapped with the first overlapped area.

In an exemplary implementation, the second overlapped area is within the range of the first overlapped area.

In an exemplary implementation, the first shield electrode 34 is connected with the second plate 32 of the storage capacitor, and the second plate 32 of the storage capacitor is connected with the first power supply line 51 through a via.

In an exemplary implementation, the first shield electrode 34 may be a strip shape of which a main body portion extends along the second direction Y, disposed at a side of the second plate 32 close to the first scan signal line 21, and an orthographic projection of an end of the first shield electrode 34 away from the second plate 32 on the plane of the display substrate is at least partially overlapped with an orthographic projection of the first scan signal line 21 on the plane of the display substrate.

In an exemplary implementation, the pixel drive circuit may include a second shield electrode 35 configured to shield the influence of the data voltage jump on the key node, which avoids the data voltage jump affecting the potential of the key node of the pixel drive circuit, and improves the display effect.

In an exemplary implementation, the second shield electrode 35 may be connected with the first power supply line 51, and an orthographic projection of the second shield electrode 35 on the base substrate is at least partially overlapped with an orthographic projection of a fourth active layer of the fourth transistor T4 on the base substrate.

In an exemplary implementation, the second shield electrode 35 may include a first sub-electrode and a second sub-electrode connected with each other, an orthographic projection of the first sub-electrode on the base substrate may be at least partially overlapped with an orthographic projection of the data signal line 44 on the base substrate, an orthographic projection of the second sub-electrode on the base substrate is located between the orthographic projection of the data signal line 44 on the base substrate and the orthographic projection of the first connection electrode 41 on the base substrate.

In an exemplary implementation, in a plane perpendicular to the display substrate, the display substrate includes a semiconductor layer, a first conductive layer, a second conductive layer, a third conductive layer, a fourth conductive layer and that are sequentially disposed on the base substrate. The semiconductor layer may include active layers of a plurality of transistors, the first conductive layer may include a first scan signal line 21, a second scan signal line 22, a light emitting control line 23, a first plate 24 of a storage capacitor, and gate electrodes of the plurality of transistors, the second conductive layer may include an initial signal line 31, a second plate 32 of the storage capacitor, a first shield electrode 34 and a second shield electrode 35, the third conductive layer may include a data signal line 44 and a first connection electrode 41, and the fourth conductive layer may include a first power supply line 51.

In an exemplary implementation, the first shield electrode 34 and the second plate 32 of the storage capacitor disposed in the same layer may form an integrated structure connected with each other.

In an exemplary implementation, the display substrate may include a first insulation layer, a second insulation layer, a third insulation layer, a fourth insulation layer and a fifth insulation layer. The first insulation layer is arranged between the base substrate and the semiconductor layer, the second insulation layer is arranged between the semiconductor layer and the first conducting layer, the third insulation layer is arranged between the first conducting layer and the second conducting layer, the fourth insulation layer is arranged between the second conducting layer and the third conducting layer, and the fifth insulation layer is arranged between the third conducting layer and the fourth conducting layer.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation and chemical vapor deposition, the coating may be any one or more of spray coating, spin coating and inkjet printing, and the etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a size of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary embodiment, taking one pixel unit as an example, the manufacturing process of the display substrate may include the following operations.

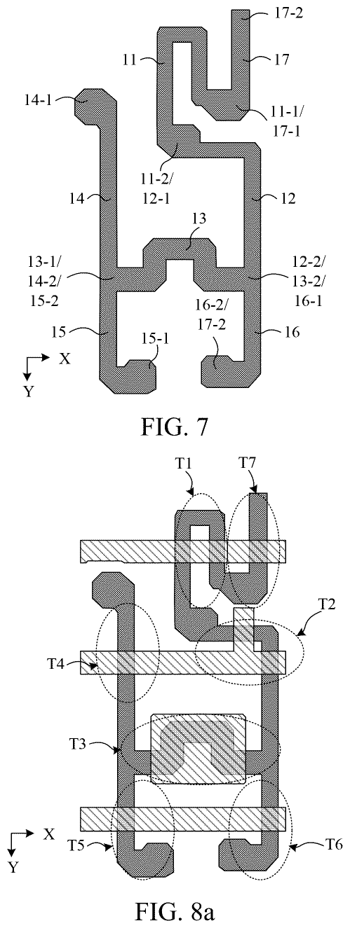

(1) A pattern of a semiconductor layer is formed. In an exemplary embodiment, forming a pattern of a semiconductor layer may include: depositing sequentially a first insulating thin film and a semiconductor thin film on a base substrate, and patterning the semiconductor thin film through a patterning process to form a first insulation layer overlying the base substrate and a semiconductor layer disposed on the first insulation layer, as shown in FIG. 7.

In an exemplary embodiment, the semiconductor layer may include a first active layer 11 of the first transistor T1 to a seventh active layer 17 of the seventh transistor T7, and the first active layer 11 to the seventh active layer 17 are of an integrated structure connected with one another.

In an exemplary embodiment, the first active layer 11, the second active layer 12, the fourth active layer 14 and the seventh active layer 17 are located on the opposite side of the third active layer 13 in the second direction Y, the fifth active layer 15 and the sixth active layer 16 are located at a side of the third active layer 13 in the second direction Y, and the first active layer 11 and the seventh active layer 17 are located at a side of the second active layer 12 and the fourth active layer 14 away from the third active layer 13.

In an exemplary implementation, the first active layer 11 may be in a “n” shape, the second active layer 12 may be in a “7” shape, the third active layer 13 may be in a shape of a Chinese character “ [symbol] ”, the fourth active layer 14 may be in a “I” shape, and the fifth active layer 15, the sixth active layer 16 and the seventh active layer 17 may be in an “L” shape.

In an exemplary implementation, an active layer of each transistor may include a first region, a second region, and a channel region located between the first region and the second region. In an exemplary embodiment, a first region 11-1 of the first active layer 11 simultaneously serves as a first region 17-1 of the seventh active layer 17, a second region 11-2 of the first active layer 11 simultaneously serves as a first region 12-1 of the second active layer 12, a first region 13-1 of the third active layer 13 simultaneously serves as a second region 14-2 of the fourth active layer 14 and a second region 15-2 of the fifth active layer 15, that is, the first region 13-1 of the third active layer 13, the second region 14-2 of the fourth active layer 13 and the second region 15-2 of the fifth active layer 15 are connected with each other. A second region 13-2 of the third active layer 13 simultaneously serves as a second region 12-2 of the second active layer 12 and a first region 16-1 of the sixth active layer 16, that is, the second region 13-2 of the third active layer 13, the second region 12-2 of the second active layer 12 and the first region 16-1 of the sixth active layer 16 are connected with each other. A second region 16-2 of the sixth active layer 16 simultaneously serves as a second region 17-2 of the seventh active layer 17. In an exemplary embodiment, a first region 14-1 of the fourth active layer 14 and a first region 15-1 of the fifth active layer 15 are disposed separately.

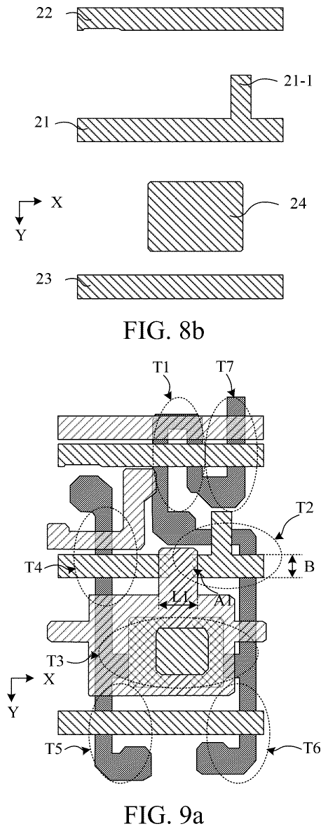

(2) A pattern of a first conductive layer is formed. In an exemplary embodiment, forming a pattern of a first conductive layer may include: sequentially depositing a second insulating thin film and a first conductive thin film on the base substrate on which the above-mentioned pattern is formed, and patterning the first conductive thin film through a patterning process to form a second insulation layer that covers a pattern of the semiconductor layer and form a pattern of the first conductive layer disposed on the second insulation layer; as shown in FIG. 8a and FIG. 8b, and FIG. 8b is a planar schematic diagram of the first conductive layer in FIG. 8a. In an exemplary embodiment, the first conductive layer may be referred to as a first gate metal (GATE1) layer.

Referring to FIGS. 7-8B, the pattern of the first conductive layer of each circuit unit may at least include the first scan signal line 21, the second scan signal line 22, the light emitting control line 23, and the first plate 24 of the storage capacitor.

In an exemplary embodiment, the main body portions of the first scan signal line 21, the second scan signal line 22, and the light emitting control line 23 may extend along the first direction X, the first scan signal line 21 and the second scan signal line 22 may be located on the opposite side of the first plate 24 in the second direction Y, the light emitting control line 23 may be located at a side of the first plate 24 in the second direction Y, and the first plate 24 of the storage capacitor may be disposed between the first scan signal line 21 and the light emitting control line 23.

In an exemplary embodiment, the first plate 24 may be rectangular, and rectangle corners may be set with chamfer. There is an overlapped area between an orthographic projection of the first plate 24 on the base substrate and an orthographic projection of the third active layer 13 on the base substrate. In an exemplary embodiment, the first plate 24 may simultaneously serve as a plate of the storage capacitor and a gate electrode of the third transistor T3.

In an exemplary embodiment, a region where the first scan signal line 21 and the second active layer 12 are overlapped serves as a gate electrode of the second transistor T2, the first scan signal line 21 is provided with a gate block 21-1 protruding toward a side of the second scan signal line 22, and there is an overlapped region between an orthographic projection of the gate block 21-1 on the base substrate and an orthographic projection of the second active layer 12 on the base substrate to form the second transistor T2 with a double gate structure. An area where the first scan signal line 21 overlaps with the fourth active layer 14 serves as the gate electrode of the fourth transistor. An area where the second scan signal line 22 overlaps with the first active layer 11 serves as the gate electrode of the first transistor T1 with a double-gate structure. An area where the second scan signal line 22 overlaps with the seventh active layer 17 serves as the gate electrode of the seventh transistor T7. An area where the light emitting control line 23 is overlapped with the fifth active layer 15 serves as a gate electrode of a fifth transistor T5, and an area where the light emitting control line 23 is overlapped with the sixth active layer 16 serves as the gate electrode of the sixth transistor T6.

In an exemplary embodiment, after the pattern of the first conductive layer is formed, the semiconductor layer may be subjected to a conductive treatment by using the first conductive layer as a shield. A region of the semiconductor layer, which is shielded by the first conductive layer, forms channel regions of the first transistor T1 to the seventh transistor T7, and a region of the semiconductor layer, which is not shielded by the first conductive layer, is made to be conductive, that is, first regions and second regions of the first active layer to the seventh active layer are all made to be conductive.

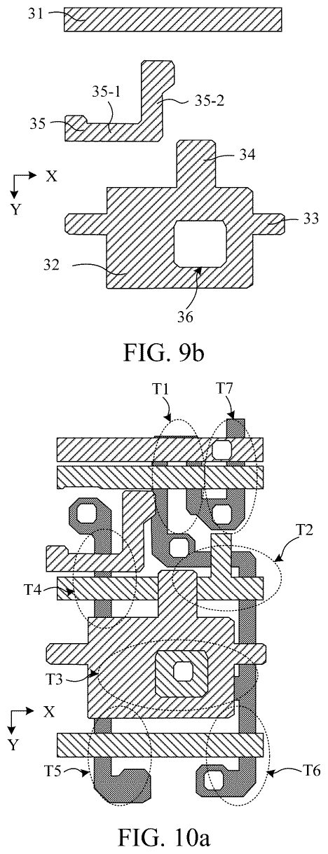

(3) A pattern of a second conductive layer is formed. In an exemplary embodiment, forming a pattern of a second conductive layer may include: a third insulation thin film and a second conductive thin film are sequentially deposited on the base substrate on which the aforementioned patterns are formed, and the second conductive thin film is patterned through a patterning process to form a third insulation layer that covers the first conductive layer and the pattern of the second conductive layer disposed on the third insulation layer, as shown in FIG. 9a and FIG. 9b. FIG. 9b is a schematic plan view of the second conductive layer in FIG. 9a. In an exemplary embodiment, the second conductive layer may be referred to as a second gate metal (GATE2) layer.

As shown in conjunction with FIGS. 7 to 9b, the pattern of the second conductive layer of each circuit unit at least includes an initial signal line 31, a second plate 32 of the storage capacitor, a plate connection line 33, a first shield electrode 34 and a second shield electrode 35.

In an exemplary embodiment, the main body portion of the initial signal line 31 may extend along the first direction X, the initial signal line 31 may be located at a side of the second scan signal line 22 away from the first scan signal line 21, the second plate 32 as the other plate of the storage capacitor is located between the first scan signal line 21 and the light emitting control line 23, the first shield electrode 34 may be located at a side of the second plate 32 close to the first scan signal line 21, and the second shield electrode 35 may be located between the first scan signal line 21 (excluding the main body portion of the gate block 21-1) and the second scan signal line 22.

In an exemplary embodiment, a profile of second plate 32 may be in the shape of a rectangle, corners of which in shape of the rectangle may be provided with a chamfer. There is an overlapped area between an orthographic projection of the second plate 32 on the base substrate and an orthographic projection of the first plate 24 on the base substrate, the first plate 24 and the second plate 32 form the storage capacitor of the pixel drive circuit.

In an exemplary embodiment, the second plate 32 is provided with an opening 36, and the opening 36 may be located in a middle of the second plate 32. The opening 36 may be rectangular and makes the second plate 32 form an annular structure. The opening 36 exposes the third insulation layer covering the first plate 24, and an orthographic projection of the first plate 24 on the base substrate contains an orthographic projection of the opening 36 on the base substrate. In an exemplary embodiment, the opening 36 is configured to accommodate a first via subsequently formed, and the first via is located within the opening 36 and exposes the first plate 24, so that a first connection electrode subsequently formed is connected with the first plate 24.

In an exemplary embodiment, the plate connection line 33 may be disposed at a side of the second plate 32 in the first direction X and in an opposite direction of the first direction X, a first end of the plate connection line 33 is connected with the second plate 32 of the present circuit unit, and a second end of the plate connection line 33 extends along the first direction X or the opposite direction of the first direction X and is connected with a second plate 32 of an adjacent circuit unit, that is, the plate connection line 33 is configured to enable second plates 32 of adjacent circuit units in one circuit unit row to be connected with each other. In an exemplary embodiment, second plates of a plurality of circuit units in one circuit unit row form an integrated structure connected with each other through the plate connection line 33, and the second plates with the integrated structure may be reused as a power supply signal line, thus ensuring that a plurality of second plates in one circuit unit row have a same potential, which is conducive to improving uniformity of the panel, avoiding a poor display of the display substrate and ensuring a display effect of the display substrate.

In an exemplary embodiment, the first shield electrode 34 may be in a strip shape extending along the second direction Y, may be disposed at a side of the second plate 32 close to the first scan signal line 21, and forms an integrated structure connected with the second plate 32. An orthographic projection of an end of the first shield electrode 34 away from the second plate 32 on the base substrate is at least partially overlapped with an orthographic projection of the first scan signal line 21 on the base substrate. The first shield electrode 34 is configured to shield the influence of the voltage jump of the first scan signal on the third transistor T3, to prevent the voltage jump of the first scan signal from affecting the performance of the drive transistor, and to improve the display effect.

In an exemplary embodiment, the first scan signal line 21 of which the main body portion extends along the first direction X has a width B in the overlapped area, and the first shield electrode 34 of which the main body portion extends along the second direction Y has a first width L1 in the overlapped area, and the width B and the first width L1 refer to dimensions perpendicular to the extending direction thereof.

In an exemplary embodiment, the orthographic projection of the first shield electrode 34 on the base substrate and the orthographic projection of the first scan signal line 21 on the base substrate have a first overlapped area A1, the area of the first overlapped area A1 is about A1=L1*B, the first width L1 is a dimension in the first direction X, and the first width B is a dimension in the second direction Y.

In an exemplary embodiment, the second shield electrode 35 is configured to shield the influence of the data voltage jump on the key node, prevent the data voltage jump from affecting the potential of the key node of the pixel drive circuit, and improve the display effect. The second shield electrode 35 may be in an “L” shape and may include a first sub-electrode 35-1 and a second sub-electrode 35-2, a first end of the first sub-electrode 35-1 is located at a side away from the first shield electrode 34, a second end of the first sub-electrode 35-1 is connected with a first end of the second sub-electrode 35-2 after extending along the first direction X, and a second end of the second sub-electrode 35-2 is located at a side of the first initial line 31 close to the first shield electrode 34 after extending in the opposite direction of the second direction Y.

In an exemplary embodiment, an orthographic projection of the first sub-electrode 35-1 on the base substrate may be at least partially overlapped with the orthographic projection of the fourth active layer 14 on the base substrate, and an orthographic projection of the first sub-electrode 35-1 on the base substrate may be at least partially overlapped with the orthographic projection of the subsequently formed data signal lines on the base substrate.

In an exemplary embodiment, an orthographic projection of the second sub-electrode 35-2 on the base substrate may be located between the orthographic projection of the subsequently formed data signal line on the base substrate and the orthographic projection of the subsequently formed first connection electrode on the base substrate.

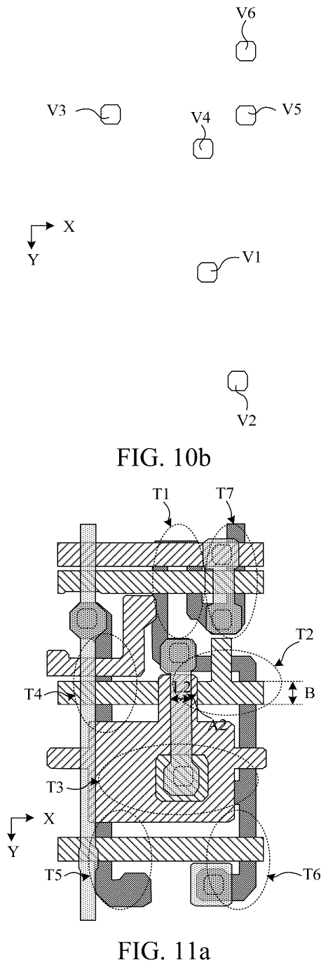

(4) A pattern of a fourth insulation layer is formed. In an exemplary embodiment, forming a pattern of a fourth insulation layer may include: depositing a fourth insulation thin film on the base substrate on which the above-mentioned patterns are formed, and patterning the fourth insulation thin film through a patterning process to form a fourth insulation layer covering the second conductive layer, wherein the fourth insulation layer is provided with a plurality of vias, as shown in FIG. 10a and FIG. 10b, and FIG. 10b is a planar schematic diagram of the plurality of vias in FIG. 10a.

As shown in conjunction with FIGS. 7 to 10b, the plurality of vias of each circuit unit at least includes a first via V1, a second via V2, a third via V3, a second via V2, a third via V3, a fourth via V4, a fifth via V5, an eighth via V8, and a sixth via V6.

In an exemplary embodiment, an orthographic projection of the first via V1 on the base substrate may be located within a range of the orthographic projection of the opening 36 on the base substrate, and the fourth insulation layer and the third insulation layer in the first via V1 are etched off to expose a surface of the first plate 24. The first via V1 is configured such that the first connection electrode formed subsequently (the second electrode of the first transistor T1 and the first electrode of the second transistor T2) is connected with the first plate 24 through the via.

In an exemplary embodiment, an orthographic projection of the second via V2 may be located within a range of an orthographic projection of the sixth active layer. The fourth insulation layer, the third insulation layer, and the second insulation layer in the second via V2 are etched away to expose a surface of the second region of the sixth active layer (which is also the second region of the seventh active layer). The second via V2 is configured such that the second electrode of the subsequently formed sixth transistor T6 (the second electrode of the seventh transistor T7) is connected with the second region of the sixth active layer through the via.

In an exemplary embodiment, an orthographic projection of the third via V3 on the base substrate may be located within a range of an orthographic projection of the fourth active layer on the base substrate. The fourth insulation layer, the third insulation layer and the second insulation layer in the third via V3 is etched away to expose a surface of the first region of the fourth active layer. The third via V3 is configured such that the data signal line formed subsequently is connected with the first region of the fourth active layer through the via.

In an exemplary embodiment, an orthographic projection of the fourth via V4 on the base substrate may be located within a range of the orthographic projection of the second active layer on the base substrate. The fourth insulation layer, the third insulation layer, and the second insulation layer in the fourth via V4 are etched away to expose a surface of the first region of the second active layer (which is also the second region of the first active layer). The fourth via V4 is configured such that the first connection electrode formed subsequently (the second electrode of the first transistor T1 and the first electrode of the second transistor T2) is connected with the first region of the second active layer through the via.

In an exemplary embodiment, an orthographic projection of the fifth via V5 on the base substrate may be located within a range of an orthographic projection of the seventh active layer on the base substrate, and the fourth insulation layer, the third insulation layer, and the second insulation layer in the fifth via V5 are etched off to expose a surface of a first region of the seventh active layer (which is also a first region of the first active layer). The fifth via V5 is configured such that a first electrode of the seventh transistor T7 subsequently formed (the first electrode of the first transistor T1) is connected with the first region of the seventh active layer through the via.

In an exemplary embodiment, an orthographic projection of the sixth via V6 on the base substrate may be located within a range of the orthographic projection of the initial signal line 31 on the base substrate. The fourth insulation layer in the sixth via V6 is etched away to expose a surface of the initial signal line 31. The sixth via V6 is configured such that the first electrode of the seventh transistor T7 (i.e., the first electrode of the first transistor T1) to be formed subsequently is connected with the initial signal line 31 through the via.

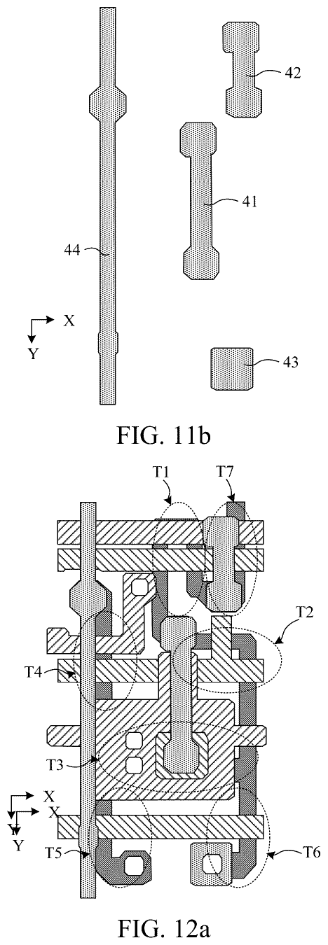

(5) A pattern of a third conductive layer is formed. In an exemplary embodiment, forming the third conductive layer may include: depositing a third conductive thin film on the base substrate on which the above-mentioned patterns are formed, and patterning the third conductive thin film through a patterning process to form the third conductive layer disposed on the fourth insulation layer, as shown in FIG. 11a and FIG. 11b, and FIG. 11b is a planar schematic diagram of the third conductive layer in FIG. 11a. In an exemplary embodiment, the third conductive layer may be referred to as a first source-drain metal layer (SD1).

As shown in conjunction with FIGS. 7 to 11b, the third conductive layer at least includes a first connection electrode 41, a second connection electrode 42, a third connection electrode 43 and a data signal line 44.

In an exemplary embodiment, the main body portion of the first connection electrode 41 may extend along the second direction Y. A first end of the first connection electrode 41 is connected to the second region of the first active layer (also the first region of the second active layer) through the fourth via V4, and a second end of the first connection electrode 41 is connected to the first electrode plate 24 through the first via V1, so that the first plate 24 (the gate electrode of the third transistor T3), the second electrode of the first transistor T1 and the first electrode of the second transistor T2 have the same potential. In an exemplary embodiment, the first connection electrode 41 may be used as the second electrode of the first transistor T1 and the first electrode of the second transistor T2.

In an exemplary embodiment, the orthographic projection of the first connection electrode 41 on the base substrate is at least partially overlapped with the orthographic projection of the first scan signal line 21 on the base substrate, and the orthographic projection of the first connection electrode 41 on the base substrate is at least partially overlapped with the orthographic projection of the first shield electrode 34 on the base substrate.

In an exemplary embodiment, the second connection electrode 42 has a first end connected with the initial signal line 31 through the sixth via V6, and a second end connected with the first region of the seventh active layer (which is also the first region of the first active layer) through the fifth via V5, so that the first electrode of the seventh transistor T7 and the first electrode of the first transistor T1 have the same potential as the initial signal line 31. In an exemplary embodiment, the second connection electrode 42 may serve as the first electrode of the first transistor T1 and the first electrode of the seventh transistor T7.

In an exemplary embodiment, the third connection electrode 43 is connected with the second region of the sixth active layer (which is also the second region of the seventh active layer) through the second via V2, so that the second electrode of the sixth transistor T6 and the second electrode of the seventh transistor T7 have a same potential. In an exemplary embodiment, the third connection electrode 43 may be used as the second electrode of the sixth transistor T6 and the second electrode of the seventh transistor T7. In an exemplary embodiment, the third connection electrode 43 is configured to be connected with an anode connection electrode formed subsequently.

In an exemplary embodiment, the main body portion of the data signal line 44 may extend along the second direction Y. The data signal line 44 is connected with the first region of the fourth active layer through the third via V3 and writes the data signal to the first electrode of the fourth transistor T4.

In an exemplary embodiment, the first scan signal line 21 of which the main body portion extends along the first direction X has a width B in the overlapped area, and the first connection electrode 41 of which the main body portion extends along the second direction Y has a second width L2 in the overlapped area, and the width B and the second width L2 refer to dimensions perpendicular to the extending direction thereof.

In an exemplary embodiment, the orthographic projection of the first connection electrode 41 on the base substrate and the orthographic projection of the first scan signal line 21 on the base substrate have a second overlapped area A2, the area of the second overlapped area A2 is about A2-L2*B, the second width L2 is a dimension in the first direction X, and the first width B is a dimension in the second direction Y.

The second overlapped area A2 may be located within the range of the first overlapped area A1, i.e. the contour of the first overlapped area A1 may include the contour of the second overlapped area A2.

In an exemplary embodiment, the first width L1 may be greater than or equal to the second width L2, i.e. the area of the first overlapped area A1 may be greater than or equal to the area of the second overlapped area A2.

In an exemplary embodiment, the second width L2 may be about 40% to 60% of the first width L1.

In an exemplary embodiment, the first width L1 may be about 2.5 μm to 3.0 μm, and the second width L2 may be about 1.3 μm to 2.0 μm.

In an exemplary embodiment, the first shield electrode 34 may shelter an overlapped area of the first connection electrode 41 and the first scan signal line 21 in the plane parallel to the base substrate, and the first shield electrode 34 is located between the first scan signal line 21 and the first connection electrode 41 in the plane perpendicular to the base substrate. Since the first shield electrode 34 is connected with the first power supply line formed subsequently, the first shield electrode 34 can effectively shield the influence of the voltage jump of the scan signal in the first scan signal line 21 on the first connection electrode 41, thereby effectively avoiding the influence of the voltage jump of the scan signal in the first scan signal line 21 on the gate electrode of the third transistor T3, ensuring the performance of the third transistor T3 and improving the display effect.

In an exemplary embodiment, since the orthographic projection of the first sub-electrode 35-1, in the second shield electrode 35, on the base substrate is at least partially overlapped with the orthographic projection of the data signal line 44 on the base substrate, an orthographic projection of the second sub-electrode 35-2 in the second shield electrode 35 on the base substrate is located between the orthographic projection of the data signal line 44 on the base substrate and the orthographic projection of the first connection electrode 41 on the base substrate, and the second shield electrode 35 is connected with the subsequently formed first power supply line, the second shield electrode 35 can effectively shield the influence of the data voltage jump on the key node in the pixel drive circuit, avoid the data voltage jump affecting the potential of the key node of the pixel drive circuit, and improve the display effect.

In an exemplary embodiment, the second shield electrodes 35 in adjacent circuit units in the first direction X may be connected with each other to reduce resistance.

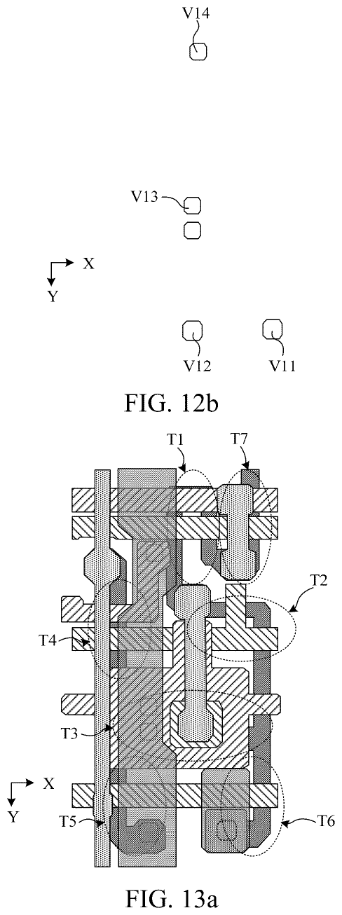

(6) A pattern of a first planarization layer is formed. In an exemplary embodiment, forming a pattern of a first planarization layer may include: coating a first planarization thin film on the base substrate on which the above-mentioned patterns are formed, and patterning the first planarization thin film through a patterning process to form a first planarization layer covering the third conductive layer, wherein the first planarization layer is provided with a plurality of vias, as shown in FIG. 12a and FIG. 12b, and FIG. 12b is a planar schematic diagram of the plurality of vias in FIG. 12a.

Referring to FIGS. 7-12b, the plurality of vias of each circuit unit at least include an eleventh via V11, a twelfth via V12, a thirteenth via V13, and a fourteenth via V14.

In an exemplary embodiment, an orthographic projection of the eleventh via V11 on the base substrate is located within a range of an orthographic projection of the third connection electrode 43 on the base substrate. The first planarization layer in the eleventh via V11 is removed to expose a surface of the third connection electrode 43. The eleventh via V11 is configured to connect the anode connection electrode formed subsequently with the third connection electrode 43 through the via.

In an exemplary embodiment, an orthographic projection of the twelfth via V12 on the base substrate is located within a range of the orthographic projection of the fifth active layer on the base substrate. The first planarization layer, the fourth insulation layer, the third insulation layer, and the second insulation layer in the twelfth via V12 are etched away to expose a surface of the first region of the fifth active layer. The twelfth via V12 is configured such that the first power supply line that is formed subsequently is connected with the first region of the fifth active layer through the via.

In an exemplary embodiment, an orthographic projection of the thirteenth via V13 on the base substrate is located within a range of an orthographic projection of the second plate 32 on the base substrate, and the first planarization layer and the fourth insulation layer in the thirteenth via V13 are etched away to expose a surface of the second plate 32. The thirteenth via V13 is configured such that the first power supply line subsequently formed is connected with the second plate 32 through the thirteenth via V13. In an exemplary embodiment, there may be a plurality of the thirteenth via V13, and the plurality of thirteenth vias V13 may be sequentially arranged along the second direction Y, thereby increasing the connection reliability between the first power supply line and the second plate 32.

In an exemplary embodiment, an orthographic projection of the fourteenth via V14 on the base substrate may be located within a range of an orthographic projection of the second shield electrode 35 on the base substrate. The first planarization layer and the fourth insulation layer in the fourteenth via V14 is etched away to expose a surface of the second shield electrode 35. The fourteenth via V14 is configured such that the first power supply line formed subsequently is connected with the second shield electrode 35 through the via.

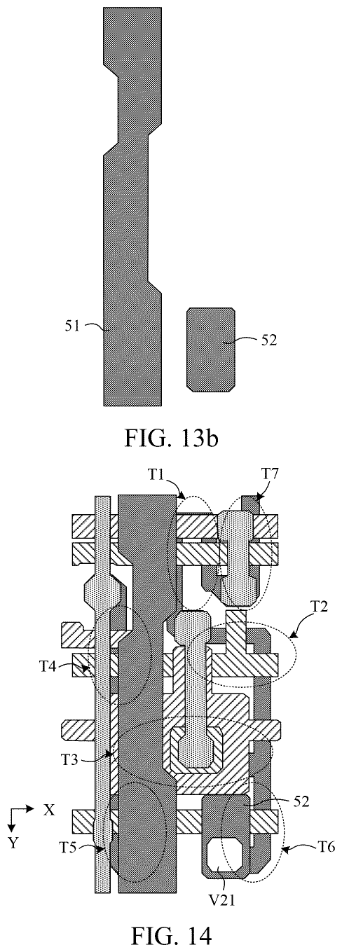

(7) A pattern of a fourth conductive layer is formed. In an exemplary embodiment, forming a pattern of a fourth conductive layer may include depositing a fourth conductive thin film on the base substrate on which the above-mentioned patterns are formed, patterning the fourth conductive thin film using a patterning process to form a fourth conductive layer disposed on the first planarization layer, as shown in FIGS. 13a and 13b, FIG. 13b is a planar schematic diagram of the fourth conductive layer in FIG. 13a.

Referring to FIGS. 7 to 13b, the fourth conductive layer at least includes a first power supply line 51 and an anode connection electrode 52.

In an exemplary implementation, the main body portion of the first power supply line 51 may extend along the second direction Y, and the first power supply line 51 may be located between the first connection electrode 41 and the data signal line 44. The first power supply line 51 is connected with the first region of the fifth active layer through the twelfth via V12, and connected with the second plate 32 through the thirteenth via V13, and connected with the second shield electrode 35 through the fourteenth via V14, so that the second plate 32, the first shield electrode 34, and the second shield electrode 35 have the same potential as the first power supply line 51, and a first power supply signal is written into the fifth transistor T5.

In an exemplary implementation, the anode connection electrode 52 may be of a shape of a rectangle and is connected with the third connection electrode 43 through the eleventh via V11. Because the third connection electrode 43 is connected with the second region of the sixth active layer (which is also the second region of the seventh active layer) through the via, thus it is achieved that the anode connection electrode 52 is connected with the second region of the sixth active layer (which is also the second region of the seventh active layer) through the third connection electrode 43.

In an exemplary embodiment, the first power supply lines 51 may be straight lines arranged at unequal widths. A first groove may be provided at a side of the first power supply line 51 close to the data signal line 44, and a second groove may be provided at a side of the first power supply line 51 close to the first connection electrode 41. The first power supply line 51 is a straight line arranged at variable widths, which not only may facilitate a layout of the pixel structures, but also may reduce parasitic capacitance between the first power supply line and the data signal line.

(8) A pattern of a second planarization layer is formed. In an exemplary embodiment, forming a pattern of a second planarization layer may include coating a second planarization thin film on the base substrate on which the above-mentioned patterns are formed, patterning the second planarization thin film using a patterning process to form the second planarization layer covering the fourth conductive layer, the second planarization layer is provided with a via, as shown in FIG. 14.

Referring to FIGS. 7 to 14, the via of each circuit unit at least includes a twenty-first via V21.

In an exemplary embodiment, an orthographic projection of the twenty-first via V21 on the base substrate is located within a range of an orthographic projection of the anode connection electrode 52 on the base substrate. The second planarization layer in the twenty-first via V21 is etched away to expose a surface of the anode connection electrode 52. In an exemplary implementation, the twenty-first via V21 is configured so that the anode formed subsequently is connected with the anode connection electrode 52 through the via.

So far, the drive circuit layer has been manufactured on the base substrate. In the plane parallel to the display substrate, the drive circuit layer may include multiple circuit units, each of the circuit units may include a pixel drive circuit, and a first scan signal line, a second scan signal line, a light emitting control line, an initial signal line, a data signal line, and a first power supply line connected with the pixel drive circuit. In a plane perpendicular to the display substrate, the drive circuit layer may include a first insulation layer, a semiconductor layer, a second insulation layer, a first conductive layer, a third insulation layer, a second conductive layer, a fourth insulation layer, a third conductive layer, a first planarization layer, a fourth conductive layer and the second planarization layer which are stacked sequentially on the base substrate.

In an exemplary implementation, after the manufacturing of the drive circuit layer is completed, an emitting structure layer may be manufactured on the drive circuit layer, and a manufacturing process of the emitting structure layer may include the following operations.

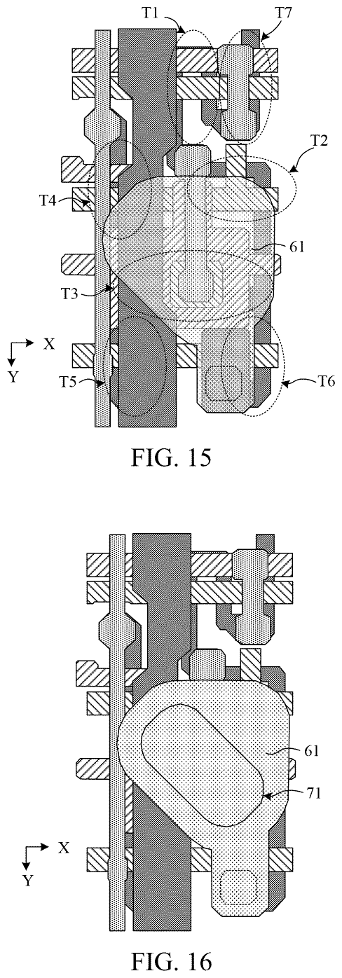

(9) A pattern of an anode is formed. In an exemplary embodiment, forming a pattern of an anode may include: depositing a fifth conductive thin film on the base substrate on which the foregoing patterns are formed, and patterning the fifth conductive thin film through a patterning process to form a pattern of an anode 61 disposed on the second planarization layer, as shown in FIG. 15.

Referring to FIG. 7 to FIG. 15, the anode 61 may be connected with the anode connection electrode 52 through the twenty-first via V21. Since the anode connection electrode 52 is connected with the third connection electrode 43 serving as the second electrode of the sixth transistor T6 and the second electrode of the seventh transistor T7 through a via, the anode 61 may be connected with the sixth transistor T6 and the seventh transistor T7 through the anode connection electrode 52 and the third connection electrode 53, so that the pixel drive circuit can drive the light emitting device to emit light.

In an exemplary embodiment, the anode 61 may include an anode body portion that may be shaped as a rectangle with rounded corners and a plurality of protrusions that may include a first protrusion and a second protrusion, both of the first protrusion and the second protrusion are connected with the anode body portion. The first protrusion can be a rectangle protruding toward the gate electrode of the second transistor T2, and is configured to adjust the parasitic capacitance of key nodes in the pixel drive circuit, reduce the difference between the parasitic capacitance of key nodes in adjacent circuit units, so as to reduce the brightness difference and improve the display effect. The second projection may be a rectangle protruding toward the anode connection electrode 52 and is configured to be connected with the anode connection electrode 52 through the twenty-first via V21.

(10) A pattern of a pixel definition layer is formed. In an exemplary embodiment, forming a pattern of a pixel definition layer may include: coating a pixel definition thin film on the base substrate on which the aforementioned pattern is formed, patterning the pixel definition thin film by a patterning process to form a pattern of a pixel definition layer, which may include a pixel opening 71 exposing the anode 61, as shown in FIG. 16.

In an exemplary implementation, a subsequent manufacturing process may include: forming an organic emitting layer using an evaporation or inkjet printing process, wherein the organic emitting layer is connected with an anode through a pixel opening, and forming a cathode on the organic emitting layer, wherein the cathode is connected with the organic emitting layer. An encapsulation layer is formed. The encapsulation layer may include a first encapsulation layer, a second encapsulation layer, and a third encapsulation layer that are stacked. The first encapsulation layer and the third encapsulation layer may be made of an inorganic material. The second encapsulation layer may be made of an organic material. The second encapsulation layer is disposed between the first encapsulation layer and the third encapsulation layer, so that it may be ensured that external water vapor cannot enter a light emitting structure layer.

In an exemplary implementation, the base substrate may be a flexible base substrate, or a rigid base substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible base substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the base substrate, and a material of the semiconductor layer may be amorphous silicon (a-si).

In an exemplary embodiment, the first conductive layer, the second conductive layer, the third conductive layer, and the fourth conductive layer may be made of metal materials, such as any one or more of silver (Ag), copper (Cu), aluminum (Al), and molybdenum (Mo), or an alloy material of the above metals, such as an Aluminum Neodymium alloy (AlNd) or a Molybdenum Niobium alloy (MoNb), and may be in a single-layer structure or a multi-layer composite structure, such as Mo/Cu/Mo. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The first insulation layer is referred to as a buffer layer for improving the water and oxygen resistance performance of the base substrate, the second insulation layer and the third insulation layer are referred to as gate insulating (GI) layers, and the fourth insulation layer is referred to as an interlayer insulating (ILD) layer. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly Silicon (p-Si), hexathiophene, or polythiophene. That is, the present disclosure is applicable to a transistor that is manufactured based on an oxide technology, a silicon technology, or an organic matter technology. The first planarization layer and the second planarization layer may be made of an organic material, such as resin. The fifth conductive layer may be made of a single-layer structure, such as indium tin oxide ITO or indium zinc oxide IZO, or may be made of a multi-layer composite structure, such as ITO/Ag/ITO, etc. The pixel define layer may be made of polyimide, acrylic or polyethylene terephthalate. The cathode may be made of any one or more of magnesium (Mg), silver (Ag), aluminum (Al), copper (Cu) and lithium (Li), or an alloy made of any one or more of the above metals.

With the development of display technologies, displays with high scanning frequency and high resolution (Pixels Per Inch, PPI for short) have become trending products, and have displaying with finer definition and higher display quality. It is found by a research that the operating performance of the drive transistor in the existing display substrate is unstable, and the operating characteristics of the drive transistor have a great influence on the high-frequency and high-resolution display. In the display substrate provided by the present disclosure, the first shield electrode is disposed in the second conductive layer, in a plane parallel to the base substrate, the first shield electrode shelters an overlapped area of the first connection electrode and the first scan signal line, and in a plane perpendicular to the base substrate, the first shield electrode is located between the first scan signal line and the first connection electrode, and the first shield electrode is connected with the first power supply line, so that the first shield electrode can effectively shield the influence of the voltage jump of the scan signal in the first scan signal line on the first connection electrode, thereby effectively avoiding the influence of the voltage jump of the scan signal in the first scan signal line on the gate electrode of the third transistor T3, thus ensuring the stability of the operating performance of the drive transistor and improving the display effect.

The manufacturing process in the present disclosure may be compatible well with an existing manufacturing process, is simple in process implementation, is easy to implement, and has a high production efficiency, a low production cost, and a high yield.

The structure shown and mentioned above in the present disclosure and the manufacturing process thereof are merely an exemplary description. In an exemplary implementation, the corresponding structures may be altered and the patterning processes may be added or reduced according to actual needs. For example, the first power supply line may be disposed in the third conductive layer (SD1), the first power supply line and the data signal line are disposed in the same layer and formed simultaneously by the same patterning process. As another example, the first shield electrode may be separately disposed and not connected with the second plate, but connected with the first power supply line formed subsequently through a via. For another example, the third conductive layer and the first planarization layer may be provided with a fifth insulation layer (PVX) or the like, and the present disclosure is not limited thereto.

In an exemplary implementation mode, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), etc., the present disclosure is not limited thereto.

The present disclosure also provides a manufacturing method of a display substrate, for manufacturing the display substrate according to the foregoing embodiments. In an exemplary implementation, the manufacturing method includes:
forming a plurality of circuit units, a scan signal line supplying a scan signal to the circuit units and a first power supply line supplying a power supply signal on the base substrate, wherein at least one circuit unit includes a pixel drive circuit including a first shield electrode connected with the first power supply line, and an orthographic projection of the first shield electrode on the base substrate is at least partially overlapped with an orthographic projection of the scan signal line on the base substrate.

The display substrate manufactured by the manufacturing method for the display substrate according to the present disclosure has similar implementation principle and implementation effect, which will not be further repeated herein.

The present disclosure also provides a display apparatus which includes the aforementioned display substrate. The display apparatus may be any product or component with a display function, such as a mobile phone, a tablet computer, a television, a display, a laptop computer, a digital photo frame, and a navigator, and the embodiment of the present disclosure is not limited thereto.

Although the implementations disclosed in the present disclosure are described as above, the described contents are only implementations which are used for facilitating the understanding of the present disclosure, but are not intended to limit the present invention. Any skilled person in the art to which the present disclosure pertains may make any modifications and variations in forms and details of implementations without departing from the spirit and scope of the present disclosure. However, the patent protection scope of the present invention should be subject to the scope defined by the appended claims.

1. A display substrate, comprising a plurality of circuit units, a scan signal line supplying a scan signal to the circuit units, and a first power supply line supplying a power supply signal; wherein at least one circuit unit comprises a pixel drive circuit comprising a first shield electrode connected with the first power supply line, an orthographic projection of the first shield electrode on a plane of the display substrate is at least partially overlapped with an orthographic projection of the scan signal line on the plane of the display substrate.

2. The display substrate according to claim 1, wherein the pixel drive circuit further comprises a drive transistor and a first plate and a second plate forming a storage capacitor, an orthographic projection of the first plate on the plane of the display substrate is at least partially overlapped with an orthographic projection of the second plate on the plane of the display substrate; the first shield electrode is connected with the second plate, and the second plate is connected with the first power supply line through a via.

3. The display substrate according to claim 2, wherein the pixel drive circuit further comprises a compensation transistor and a first connection electrode, a first end of the first connection electrode is connected with a first region of an active layer in the compensation transistor through a via, a second end of the first connection electrode is connected with the first plate through a via, and an orthographic projection of the first connection electrode on the plane of the display substrate is at least partially overlapped with an orthographic projection of the scan signal line on the plane of the display substrate.

4. The display substrate according to claim 3, wherein the orthographic projection of the first shield electrode on the plane of the display substrate and the orthographic projection of the scan signal line on the plane of the display substrate have a first overlapped area, and the orthographic projection of the first connection electrode on the plane of the display substrate and the orthographic projection of the scan signal line on the plane of the display substrate have a second overlapped area, the second overlapped area is at least partially overlapped with the first overlapped area.

5. The display substrate according to claim 4, wherein the second overlapped area is within a range of the first overlapped area.

6. The display substrate according to claim 4, wherein the first overlapped area has a first width and the second overlapped area has a second width; the first width is larger than the second width, and the first width and the second width are dimensions in a first direction.

7. The display substrate according to claim 6, wherein the second width is 40% to 60% of the first width.

8. The display substrate according to claim 6, wherein the first width is 2.5 μm to 3.0 μm.

9. The display substrate according to claim 6, wherein the second width is 1.3 μm to 2.0 μm.

10. The display substrate according to claim 2, wherein a main body portion of the scan signal line extends in a first direction, and a main body portion of the first shield electrode extends in a second direction, wherein the first direction intersects the second direction; the first shield electrode is disposed at a side of the second plate close to the scan signal line, and an orthographic projection of an end of the first shield electrode away from the second plate on the plane of the display substrate is at least partially overlapped with an orthographic projection of the scan signal line on the plane of the display substrate.

11. The display substrate according to claim 10, wherein the first shield electrode and the second plate are disposed in a same layer and form an integrated structure connected with each other.

12. The display substrate according to claim 1, wherein in a plane perpendicular to the display substrate, the display substrate comprises a semiconductor layer, a first conductive layer, a second conductive layer, a third conductive layer, and a fourth conductive layer that are sequentially disposed on a base substrate, and an insulation layer is disposed between the first conductive layer and the second conductive layer, between the second conductive layer and the third conductive layer, and between the third conductive layer and the fourth conductive layer; the first shield electrode, the first connection electrode and the scan signal line are located in different conductive layers.

13. The display substrate according to claim 12, wherein the scan signal line is disposed in the first conductive layer, the first shield electrode is disposed in the second conductive layer, and a first connection electrode is disposed in the third conductive layer.

14. The display substrate according to claim 12, wherein the semiconductor layer comprises active layers of a plurality of transistors in the pixel drive circuit, the first conductive layer comprises the scan signal line, gate electrodes of the plurality of transistors, and a first plate of the storage capacitor, the second conductive layer comprises the first shield electrode and a second plate of the storage capacitor, the third conductive layer comprises the data signal line and a first connection electrode, and the fourth conductive layer comprises the first power supply line.

15. The display substrate according to claim 14, wherein the second conductive layer further comprises a second shield electrode, the second shield electrode comprises a first sub-electrode and a second sub-electrode connected with each other, an orthographic projection of the first sub-electrode on the base substrate is at least partially overlapped with an orthographic projection of the data signal line on the base substrate, an orthographic projection of the second sub-electrode on the base substrate is located between the orthographic projection of the data signal line on the base substrate and the orthographic projection of the first connection electrode on the base substrate.

16. The display substrate according to claim 15, wherein the second shield electrode is connected with the first power supply line through a via.

17. A display apparatus, comprising a display substrate according to claim 1.

18. A manufacturing method for a display substrate, comprising:
forming a plurality of circuit units, a scan signal line supplying a scan signal to the circuit units and a first power supply line supplying a power supply signal on a base substrate, wherein at least one circuit unit comprises a pixel drive circuit comprising a first shield electrode connected with the first power supply line, and an orthographic projection of the first shield electrode on the base substrate is at least partially overlapped with an orthographic projection of the scan signal line on the base substrate.
